(19) United States
(12) Patent Application Publication
(10) Pub. No.: US 2008/0054759 A1
(43) Pub. Date: Mar. 6, 2008

(54) Wafer-level encapsulation and sealing of electrostatic transducers

(76) Inventors: Farrokh Ayazi, Atlanta, GA (US); Siavash Pourkamali Anaraki, Denver, CO (US)

Correspondence Address: Kenneth W. Float, #2F, 2095 Hwy. 211 NW, Braselton, GA, 30517, US

(21) Appl. No.: 11/891,393

(22) Filed: Aug. 10, 2007

Related U.S. Application Data
(60) Provisional application No. 60/837,120, filed on Aug. 11, 2006.

(51) Int. Cl. H03H 9/00

(52) U.S. Cl. 310/309; 310/322; 361/748

(57) ABSTRACT

Disclosed are encapsulated microelectromechanical devices that are integrated with integrated circuit devices in the same substrate. Exemplary microelectromechanical apparatus comprises a substrate, one or more movable microelectromechanical elements formed in the substrate, and one or more stationary elements that are electrically operative elements of the apparatus and that form a protective layer for the movable microelectromechanical elements. Reduced to practice devices include acoustic resonators whose stationary electrodes also encapsulate the resonators. CMOS integrated circuit devices may be formed on the substrate beside or on top of the microelectromechanical devices.

### BACKGROUND

The present invention relates generally to semiconductor processing and fabrication methods, and more particularly, to wafer-level encapsulation and sealing of electrostatic transducers, sensors, and resonators, and the like.

Packaging is one of the most critical and costly steps in microelectronic manufacturing. Packaging of movable MEMS devices is specially challenging because the package has to provide complete isolation and protection for the extremely sensitive micromechanical structures without being in physical contact with them and interfering with their operation. Furthermore, for some of the MEMS devices, such as resonant sensors, operation in vacuum is required or preferred. Therefore, low cost batch-fabrication techniques that can provide a suspended impermeable seal on top of the micromechanical structures are of great interest.

Sealing techniques have been reported that are generally based on wafer bonding or removal of a sacrificial layer from the top of the devices after deposition of a sealing layer. See B. Ziaei, et al., “A Hermetic Glass Silicon Micro Package with High-Density On-Chip Feedthroughs for Sensors and Actuators,” J. Microelectromechanical. Syst. vol. 5, pp. 166-179, 1996; Y. Mei, et al., “A Robust Gold-Silicon Eutectic Wafer Bonding Technology for Vacuum Packaging,” Tech. Dig. Solid-State Sensor and Actuator Workshop, Hilton Head Island, June 2002; L. Lin, “MEMS Post-Packaging by Localized Heating and Bonding,” IEEE Trans on Advanced Packaging, vol. 23, pp. 608-616, 2000; B. H. Stark, et al., “A Wafer-Level Vacuum Packaging Technology Utilizing Electroplated Nickel,” in ASME Congress, MEMS and Nanotechnology Symposium, New Orleans, November, 2002; P. Monajemi, et al., “A Low Cost Wafer-Level MEMS Packaging Technology,” Proc. IEEE Micro Electro Mechanical Systems Conference (MEMS'05), Miami, Fla., January 2005, pp. 634-637; and R. N. Candler, et al., “Single Wafer Encapsulation of MEMS Devices,” Trans. on Advanced Packaging, vol. 26, no. 3, pp. 227-232, 2003.

In general, packaging techniques based on wafer bonding add significant complexity and cost to the process and therefore thin-film sacrificial layer based techniques are preferred. Among interesting examples of such techniques are using thermally-decomposable polymers as sacrificial layer (see the P. Monajemi, et al. paper cited above) and epitaxial growth of silicon on top of silicon structures patterned on SOI substrates for sealing and CMOS integration (see the R. N. Candler, et al. paper cited above).

HARPSS (High Aspect Ratio Poly- and Single-crystal Silicon) fabrication is a three-dimensional silicon bulk micromachining technology with superior capabilities in embedding high-performance electrostatic sensors and actuators in silicon substrate. The unique feature of the HARPSS fabrication process is its capability to integrate nano-scale self-aligned lateral capacitive transduction gaps with thick structures made of bulk silicon and polysilicon. Several types of high resolution vibrating gyroscopes as well as high frequency high-Q silicon resonators for frequency referencing have been demonstrated using different versions of the HARPSS fabrication process. FIG. 1 shows the SEM view of a typical SiBAR (Silicon Bulk Acoustic Wave Resonator) with resonance frequency of ˜100 MHz fabricated using the HARPSS-on-SOI process as well as its width extensional resonant mode shape. The resonating body is made of SCS (Single Crystal Silicon) and its electrodes are made of polysilicon.

Several HARPSS electrostatic sensors and actuators are disclosed by F. Ayazi et al., “A HARPSS Polysilicon Vibrating Ring Gyroscope,” IEEE Journal of Microelectromechanical Systems, Vol. 10, June 2001, pp. 169-179; M. Zaman, et al., “The Resonating Star Gyroscope,” Proc. IEEE Micro Electro Mechanical Systems Conference (MEMS'05), Miami, Fla., January 2005, pp. 355-358; H. Johari et al., “High Frequency Capacitive Disk Gyroscopes in (100) and (111) Silicon,” Tech. Dig. 20th IEEE International Conference on Micro Electormechanical Systems Conference 2007, Kobe, Japan, January 2007; S. Pourkamali, et al., “High-Q Single Crystal Silicon HARPSS Capacitive Beam Resonators with Sub-micron Transduction Gaps,” IEEE Journal of Microelectromechanical Systems, Vol. 12, No. 4, August 2003, pp. 487-496; S. Pourkamali, et al., “Vertical Capacitive SiBARs,” MEMS'05, pp. 211-214; S. Pourkamali et al., “High frequency low impedance silicon BAR structures,” Proceedings, Hilton Head 2006, Solid-state Sensor, Actuator and Microsystems Workshop, pp. 284-287; and Siavash Pourkamali, “High frequency capacitive single crystal silicon resonators and coupled resonator systems,” PhD Thesis, Georgia Institute of Technology, August 2006.

It would be desirable to have improved microelectromechanical devices that have wafer-level encapsulation and fabrication methods. It would also be desirable to have encapsulated microelectromechanical devices that may be integrated or packaged with CMOS integrated circuit devices using the same substrate and fabrication methods.

### BRIEF DESCRIPTION OF THE DRAWINGS

The various features and advantages of the present invention may be more readily understood with reference to the following detailed description taken in conjunction with the accompanying drawings, wherein like reference numerals designate like structural elements, and in which:

FIG. 1 illustrates a scanning electron microscope view of an exemplary low impedance capacitive silicon bulk acoustic wave resonator (SiBAR) fabricated using a HARPSS-on-SOI process;

FIG. 2a illustrates a released SiBAR with extended poly electrodes covering its single crystal silicon resonator body;

FIG. 2b illustrates an enlarged view of a portion of FIG. 2a;

FIGS. 3a-3d illustrate of exemplary process steps in fabricating an exemplary encapsulated resonator;

FIG. 4a illustrates a SEM view of SiBARs after encapsulation by a thick PECVD oxide layer and patterning the sealing layer for electrical access to resonator pads;

FIG. 4b illustrates an enlarged view of a portion of the SiBARs shown in FIG. 4a;

FIG. 5a is a graph that illustrates measured resonance peaks for a 40 μm wide, 300 μm long, 20 μm thick SiBAR before PECVD oxide encapsulation;

FIG. 5b is a graph that illustrates measured resonance peaks for a 40 μm wide, 300 μm long, 20 μm thick SiBAR after PECVD oxide encapsulation;

FIGS. 6a to 6c are graphs that illustrate measurement results for an encapsulated resonator;

FIGS. 7a and 7b show the measured resonance peaks of the encapsulated resonator before and after dispensing in city water;

FIG. 8 illustrates a temperature induced frequency shift graph; and

FIGS. 9a-9f illustrate of exemplary process steps in fabricating an exemplary encapsulated resonator prior to fabrication of a CMOS device on the same substrate.

### DETAILED DESCRIPTION

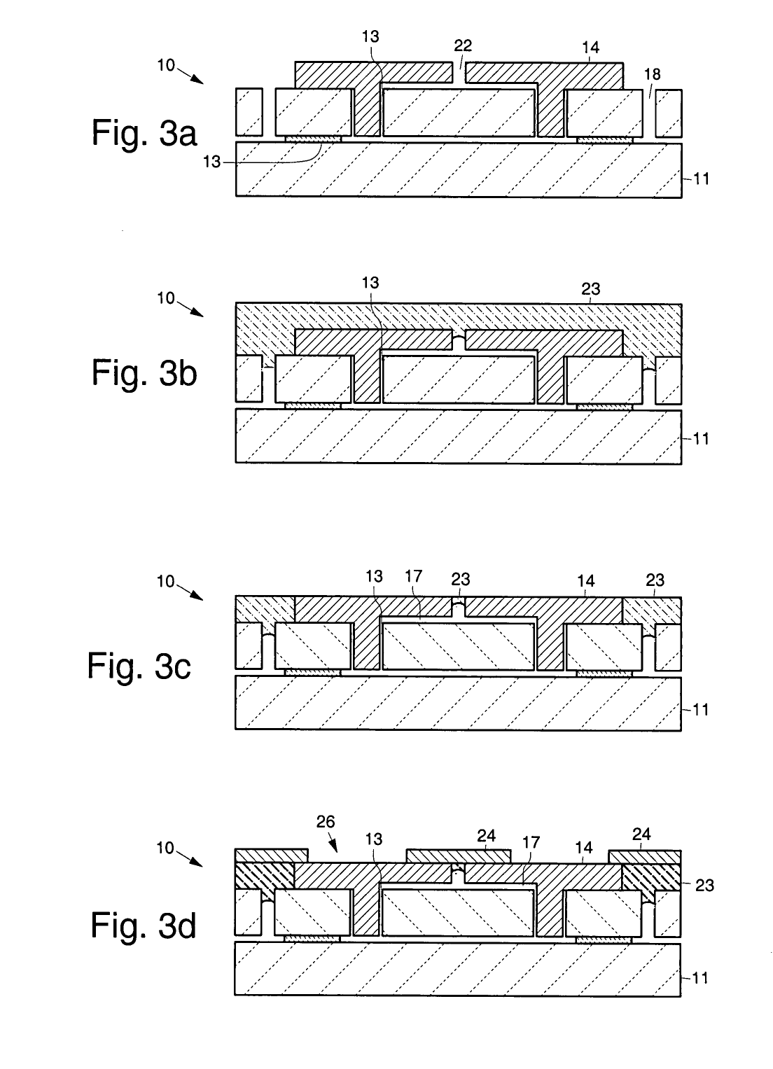

Disclosed are microelectromechanical (MEMS) devices, such as resonators, sensors, and actuators, and the like, encapsulated using a thin-film wafer-level encapsulation technique that is compatible with the well-known HARPSS process as well as regular CMOS fabricated processes. The encapsulated microelectromechanical devices may be integrated or packaged in the same substrate as CMOS devices. This technique takes advantage of the stationary parts of the microelectromechanical device for encapsulating its sensitive moving parts, and therefore can be performed without addition of extensive processing steps. Exemplary encapsulated high frequency capacitive silicon resonators 10 or devices 10 (FIGS. 2 and 3) are disclosed that were fabricated using this technique. Reliability and performance tests conducted on the encapsulated resonators reveal a high level of hermeticity and reliability with minimal interference with device operation. This technique can be applied to a wide variety MEMS sensors and actuators. Silicon transducers encapsulated using this technique can run through the conventional integrated circuit fabrication and/or packaging processes.

It has been demonstrated by the present inventors that for the single crystal silicon HARPSS-on-SOI resonators, polysilicon electrodes and their interconnects can bridge over underlying single crystal silicon (SCS) substrate structures without physically contacting them. As disclosed herein, suspended overlapping polysilicon electrodes of a silicon bulk acoustic wave resonators (SiBAR) are extended on top of the resonator, providing a suspended polysilicon cap covering the resonating body of the resonator. Complete encapsulation is then achieved by deposition of a nonconformal sealing layer to close small release openings in the polysilicon cap without affecting the underlying movable resonating structures.

Device Structure

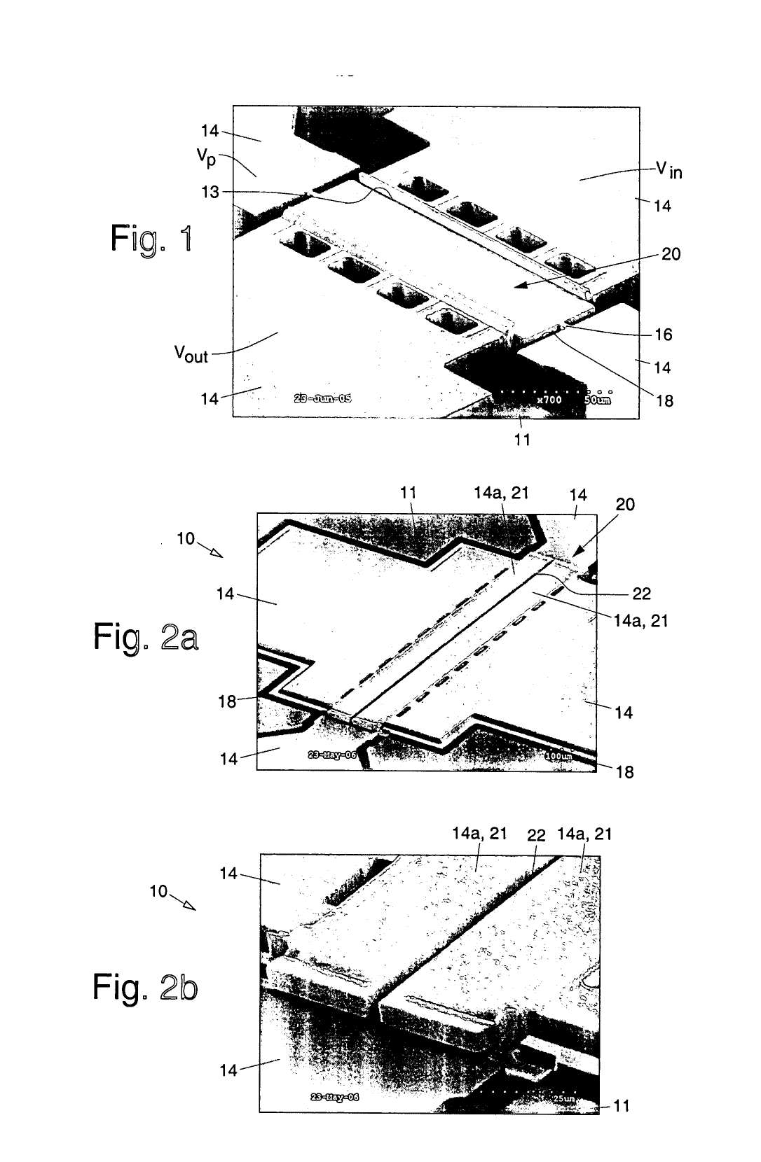

FIG. 1 shows an exemplary resonator without extended polysilicon electrodes. FIGS. 2a and 2b, illustrate an exemplary resonator (SiBAR) 10 with extended polysilicon electrodes. The encapsulated resonator 10 includes the structure illustrated in FIG. 1 and further includes an encapsulating structure, which is part of the stationary electrodes, shown in FIGS. 2a and 2b. Details regarding the design and fabrication of capacitive vertical silicon bulk acoustic resonators 10 may be had with reference to U.S. Pat. No. 7,176,770, issued Feb. 13, 2007, the contents of which are incorporated herein by reference in its entirety.

As is shown in FIG. 1, the resonator 10 comprises a single crystalline silicon (SCS) resonator element 20 and one or more electrodes 14 (or bias pads 14) that are separated from each other by nanoscale capacitive gaps 13. The resonator element 20 is connected to the bias pads 14 by one or more silicon support beams 16 disposed at respective ends of the resonator element 20. The bias pads 14 form anchors in or to the substrate 11 that allow the resonator element 20 to be suspended between the support beams 16. The electrodes 14 are disposed on adjacent sides of the resonator element 20 and are separated therefrom by capacitive gaps 13. The capacitive gaps 13 may be air gaps, or may be filed with a fluid material. As is shown in FIG. 1, the resonator element 20 is separated from adjacent edges of the respective bias pads 14 by air gaps 18 (trenches 18).

FIGS. 2a and 2b illustrate an exemplary released resonator 10 having extended electrodes 14a covering a single crystal silicon substrate 11 comprising a resonator body. More particularly, FIGS. 2a and 2b show scanning electron microscope (SEM) views of an exemplary fabricated resonator 10 having extended polysilicon electrodes 14a, comprising a polysilicon cap 21.

The cap 21 may have a narrow opening 22 formed in it along the length of the resonator element 20 that electrically isolates the respective electrodes 14a forming the cap 21. Use of two electrically isolated extended electrodes 14a provides for a two-port device. However, a single extended electrode 14a may be provided to realize a one-port device.

Exemplary Fabrication Process

Exemplary encapsulation process steps for fabricating the encapsulated resonator 10 are shown in FIGS. 3a-3d. Resonators 10, for example, may be fabricated using the well-known HARPSS-on-SOI process without any modification or extra steps added to the fabrication process, and only by making slight adjustments to the layout of the resonator 10. Although a resonator 10 is disclosed herein as an exemplary embodiment, it is to be understood that other types of devices may be also be fabricated and encapsulated, including various MEMS sensors and actuators. Changes in the layout include extended polysilicon electrodes 14a on top of the resonator 10 and a narrow opening 22 (˜1-2 μm wide) in the polysilicon cap 21 to electrically isolate the electrodes 14a and allow HF release of underlying resonating structure. In addition, to allow further lithography steps, the surrounding SOI device layer is kept on the substrate 11 while the resonator 10 is separated from it by narrow isolation trenches 18 (˜4-8 μm wide) etched down to the SOI buried oxide layer around the entire resonator 10.

After fabricating a HARPSS resonator 10 with extended electrodes 14a as shown in FIG. 3a, a thick nonconformal layer 23, such as a PECVD oxide layer 23, is deposited that gradually narrows down and closes the opening 22 in the extended electrode 14a as well as the surrounding isolation trenches 18. Finally, after deposition of 10 μm of the PECVD oxide layer 23, the trenches 18 are completely closed and covered by this thick oxide layer 23. Since PECVD layers usually suffer from excessive defects and pinholes in their structure, the PECVD oxide layer 23 that is used may not provide a strong and impenetrable layer with enough hermeticity. Therefore, as shown in FIG. 3d, one can add a dense sealing layer 24 such as a LPCVD or metal film on top of the PECVD oxide layer 23. This may preferably be done by polishing the PECVD oxide layer 23 back to the surface of the polysilicon electrodes 14a as shown in FIG. 3c while keeping the resonating structure sealed to avoid deposition of the LPCVD or metal film sealing layer 24 on top of the resonating structure.

Finally, openings 26 are etched in the sealing layer 24 to allow access to the electrodes 14a for electrical connections. A resonator 10 encapsulated using this technique can then run through the regular packaging steps used in the IC industry providing a reliable package without significant cost added to the encapsulated MEMS device compared to regular IC products. Furthermore, since the polysilicon electrodes 14a and oxide layer 23 used for encapsulating the MEMS device 10 are fully CMOS-compatible and stable at high temperatures, the encapsulated device can run through a regular CMOS fabrication and packaging process, providing MEMS products with on-chip integrated electronics without any changes or significant cost added to the regular IC fabrication process.

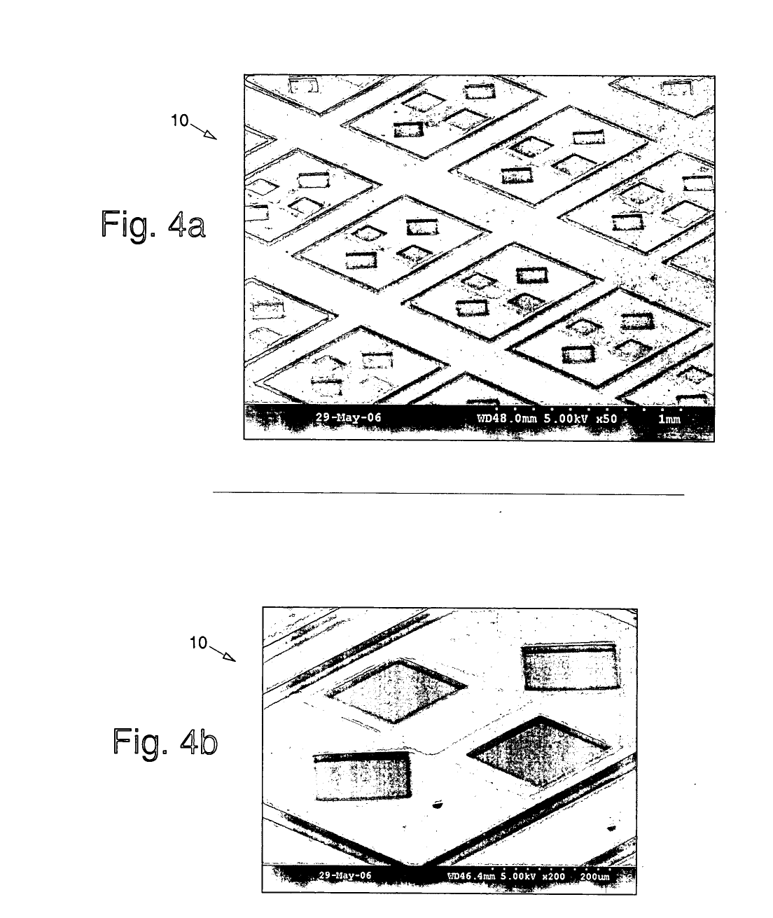

FIG. 4a illustrates a SEM view of resonators 10 after encapsulation by a thick PECVD oxide layer 23 and patterning the sealing layer for electrical access to resonator pads, and FIG. 4b illustrates an enlarged view of a portion of the resonators 10 shown in FIG. 4a.

FIG. 4a illustrates a number of encapsulated resonators 10 with different resonant frequencies batch-fabricated on an SOI substrate 11. As is discussed below, the thick PECVD oxide layer 23 used in fabricating reduced-to-practice resonators 10 turned out to provide a good enough seal with excellent resistance against gas and liquid penetration inside the cavity, and successfully passed reliability and endurance tests that were performed. Therefore, the resonators 10 are sealed and isolated from the outside only by the thick PECVD oxide layer 23 and unremoved photoresist used to pattern the oxide layer 23.

Endurance and Reliability Tests

Several tests were performed on a number of the encapsulated resonators 10 to investigate the strength and reliability of the sealing layers against penetration of liquid or gas molecules in and out of the resonator cavity as well as the effects of the encapsulation process on resonator performance.

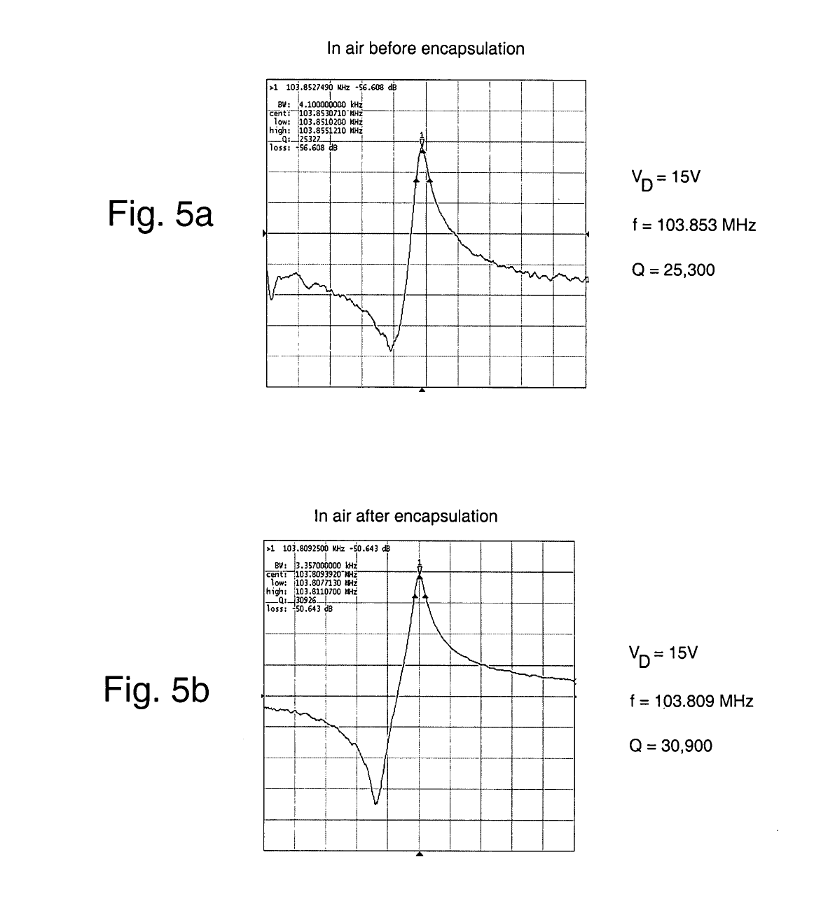

To observe the effect of the encapsulation process on the characteristics of the resonator 10, some of the devices were tested in air before and after encapsulation. FIGS. 5a and 5b show the measured frequency response of a 103 MHz resonator 10 before and after encapsulation. As is illustrated in FIGS. 5a and 5b, the resonator Q increases slightly (˜22%) after encapsulation compared to its measured value in air prior to its encapsulation; this shows existence of some level of vacuum inside the sealed cavity 17. Since sealing of the cavity 17 takes place inside the PECVD chamber under 200-300 mTorr pressure, it is expected to maintain the same level of vacuum inside the cavity 17 after encapsulation in case of a perfect and impermeable seal. Therefore, it can be concluded that the deposited PECVD oxide layer 23 has a good resistance against penetration of air molecules into the cavity 17.

The difference between the Q factor of resonators 10 in air and vacuum in this frequency range is typically larger than the observed value in FIGS. 5a and 5b and a Q of at least ˜40,000-60,000 in vacuum is expected from a resonator with Q of 25,000 in air. The Q value being lower than expected could be a result of undesired deposition of very small amounts of PECVD oxide 23 on the resonator body during the encapsulation process. A slight reduction (˜420 ppm) in the resonance frequency of the resonator after encapsulation also confirms the same assumption. This can be reduced or totally avoided by increasing the thickness of the polysilicon cap 21 (4 μm) and/or decreasing its opening width.

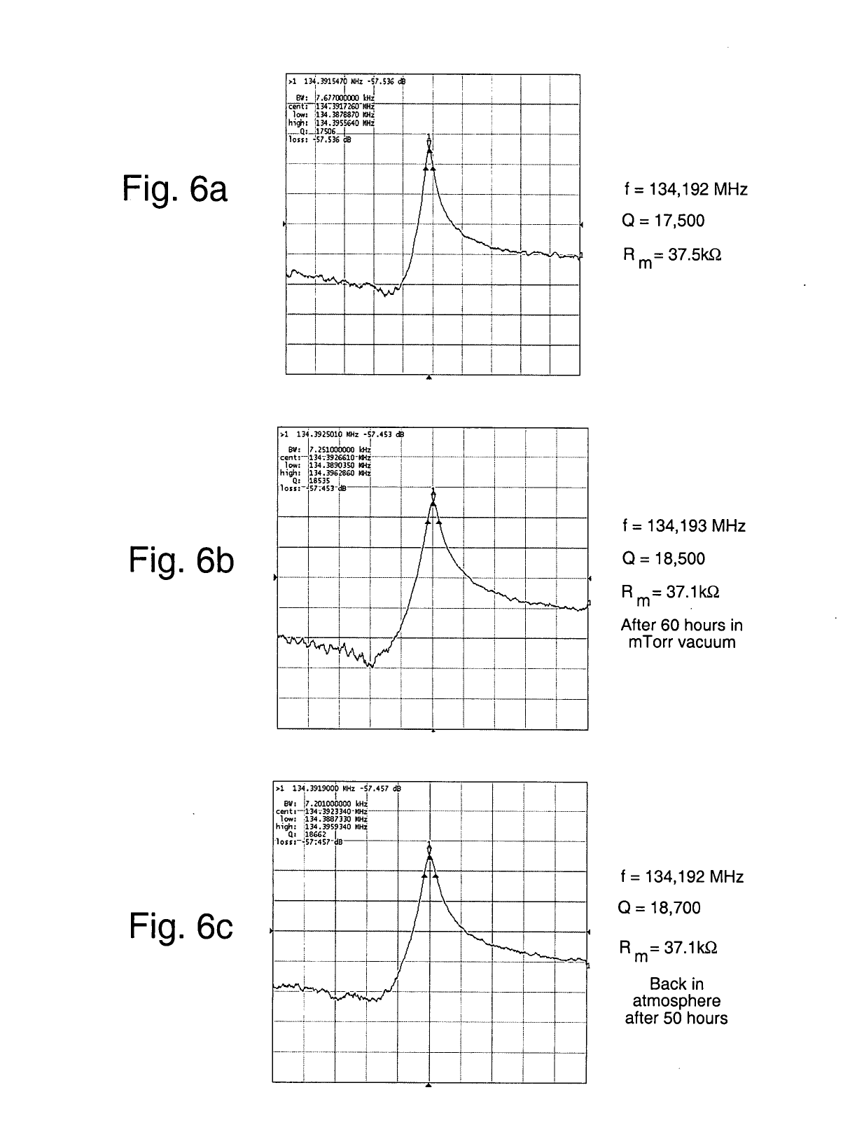

To further investigate the resistance of the seal against air pressure, comparatively long term tests were performed on exemplary resonators 10. The encapsulated resonators 10 were first measured in air and then placed under vacuum for a period of 60 hours. The resonant frequency and quality factor of the resonators 10 were observed and recorded at intervals of a few hours. The resonators 10 were then transferred back to the atmosphere and kept under measurement for another 50 hours. FIGS. 6a-6c show measured resonance peaks of an encapsulated 134 MHz resonator 10 in atmosphere, under mTorr level vacuum and back to atmosphere. Resonator Q was constant during the test period and independent of the pressure of its surrounding environment. Slight changes in the measured values of quality factor are in the order of measurement uncertainties and/or test set-up effects, and are much smaller than the environmental-pressure-induced Q variations, which further indicates the impermeability of the PECVD oxide seal.

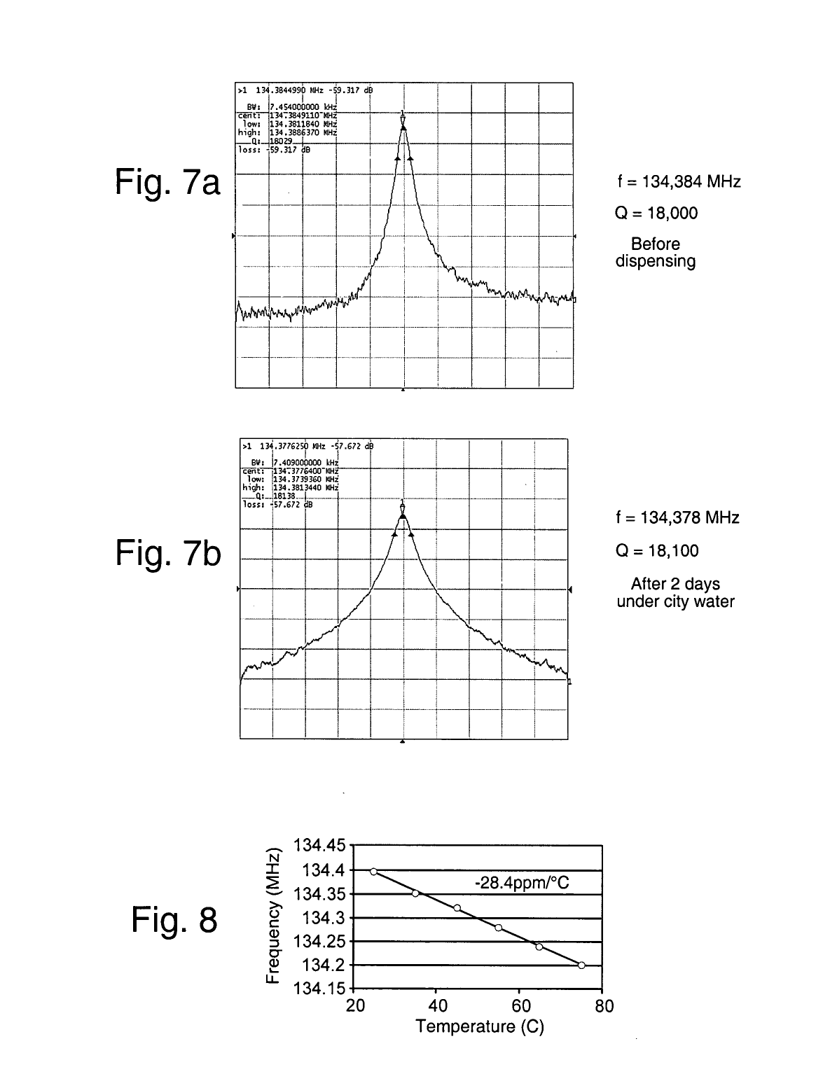

After leaving the encapsulated resonator 10 in the lab with no protection for over two weeks, to determine the resistance of the seal against liquids, the sample was dispensed in a used paper cup filled with city water and was left there for over two days. The resonator 10 was then taken out of the water, and after blowing the remaining liquid off its surface, the same resonator 10 was tested again and a similar resonance peak with the same resonant frequency and the same quality factor was observed. This indicates the hermeticity of the oxide seal against liquids. FIGS. 7a and 7b show the measured resonance peaks of the encapsulated resonator 10 before and after dispensing in city water. Slight change in the resonant frequency of the resonator 10 before and after the test is in the order of temperature induced frequency changes and can not be due to penetration of water into the cavity 17.

Finally, the resonator 10 was placed in a temperature controlled oven, and the oven temperature was swept from room temperature (˜25 C.°) to 75° C. The resonance frequency of the resonator 10 was measured and recorded at 10° C. intervals. FIG. 8 is a temperature induced frequency shift graph showing a similar linear trend with the same slope for the encapsulated resonator 10 as that of regular unsealed SCS HARPSS resonators. The certifies that the thick PECVD oxide layer 23 does not induce significant stress on the enclosed structures

MEMS-CMOS Integration

One of the major advantages and motivations for fully silicon capacitive resonators 10 compared to their piezoelectric counterparts is their material compatibility with silicon IC processes. For HARPSS-based fabrication processes however, the high temperature deposition and oxidation steps as well as long HF release times impose severe limitations and process incompatibilities for monolithic CMOS integration of such devices.

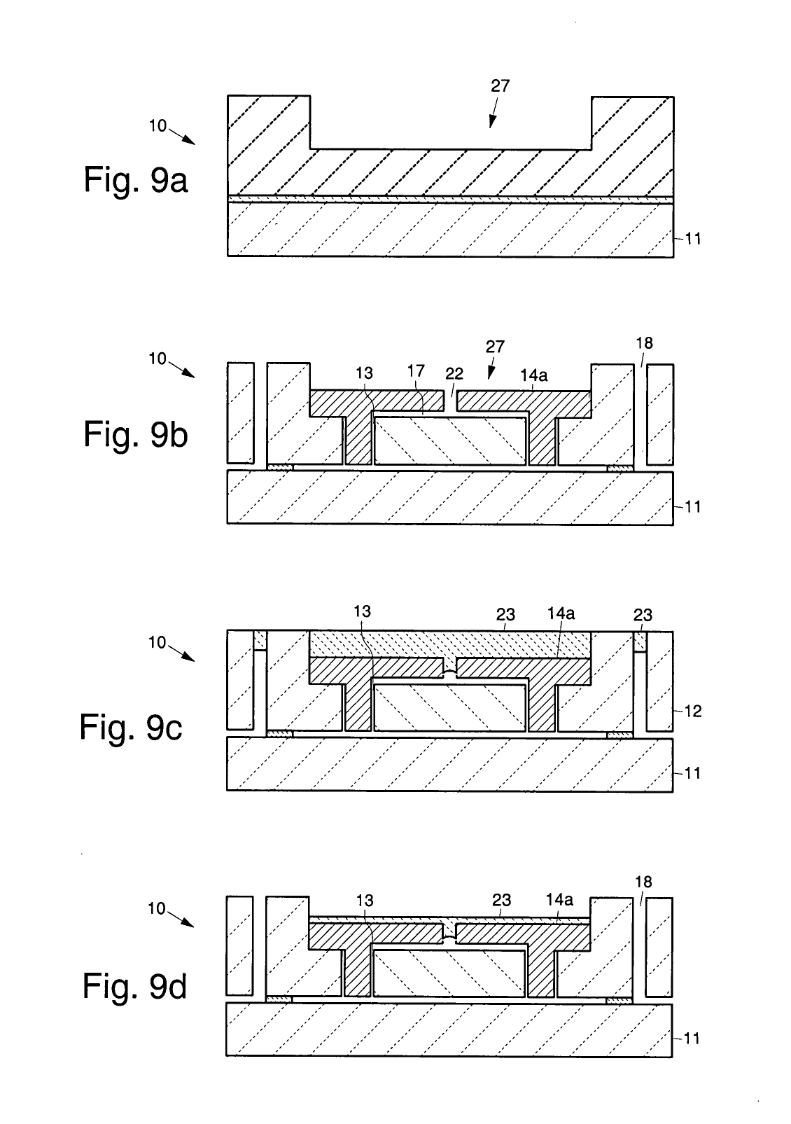

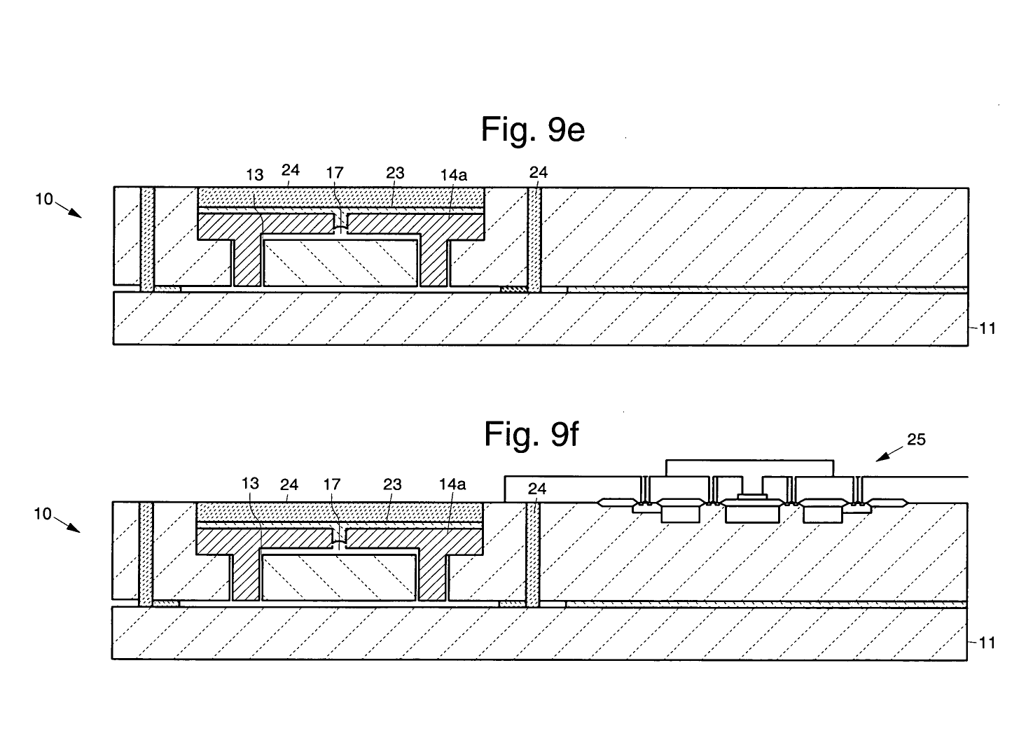

FIGS. 9a-9f illustrate exemplary process steps in fabricating an exemplary MEMS device 10 comprising an encapsulated resonator 10 prior to fabrication of a CMOS device 25 on the same substrate 11. FIGS. 9a-9f also illustrates post-MEMS 10 fabrication of integrated CMOS device 25 comprising CMOS circuitry 25 on top of a polysilicon-oxide encapsulated resonator 10. Fabrication of the MEMS device 10 is substantially as discussed with reference to FIGS. 3a-3d, except that to provide a flat surface for following CMOS lithography steps, the MEMS area is etched back a few microns (FIG. 9a) to form a recess 27 prior or after fabrication of the resonator 10 (FIGS. 9b-9d).

The polysilicon-oxide encapsulation technique discussed above is an enabling technology for this integration scheme. In this approach, the resonators 10 are fabricated, released and encapsulated first. The regular CMOS process is then performed on the silicon substrate 11 on top of, or next to, the resonators 10. If the MEMS sealing is hermetic enough, CMOS process steps do not have a destructive effect on the performance of the resonators 10.

Making interconnects between MEMS and CMOS devices 10, 25 is as simple as making a substrate contact in the CMOS process. For this purpose parts of silicon pads of the resonator 10 are formed outside the etched-back MEMS area so that they are accessible by CMOS substrate contacts. The integrated MEMS devices 10 implemented using this approach are encapsulated and conventional packaging used for CMOS IC devices 25 can be used for final packaging of such integrated devices.

Thus, a low cost batch fabrication process for wafer-level vacuum sealing of high frequency HARPSS capacitive resonators 10 has been disclosed. This fabrication technique uses stationary parts of the device itself for forming a protective cap on top of the micromechanical movable structures and requires addition of only one extra lithography step and therefore minimal added cost. The fabrication technique can be used for encapsulation of several types of HARPSS based sensors and actuators as well as other types of MEMS devices. The sealed devices can then run through the regular IC packaging process. The polysilicon and oxide films used as the cap and sealing layer in this technique are fully CMOS compatible and can tolerate high temperatures in a CMOS fabrication sequence. Therefore, similar sealing technique can be used to fabricate encapsulated MEMS devices and then run the wafers in a regular CMOS fabrication and packaging line to implement CMOS integrated MEMS sensor and actuators in a very convenient and low cost manner.

Thus, the packaging technology disclosed herein provides a reliable approach for encapsulating several types of micromechanical devices inside a substrate. The technique is based on deposition of a sacrificial layer on top of the MEMS device followed by deposition of a sealing material to cover the device completely. Small openings can then be etched in the cap. The sacrificial layer is then removed using wet or dry etching to release the movable mechanical structures inside the cap. Deposition of a nonconformal layer of material can seal the small openings in the cap while not penetrating inside the cap where the MEMS structures are located.

Several materials may be used as the cap as well as the sacrificial material. In some cases, e.g., HARPSS electrostatic transducers, the sacrificial material and/or the cap can be stationary parts of the micromechanical system, e.g., electrodes. This reduces packaging cost significantly. This technique can be employed to embed MEMS devices inside a semiconductor substrate on which electronic circuitry, e.g. CMOS circuits, are fabricated and interfaced with the MEMS devices. This approach can be used for both pre-CMOS or post-CMOS fabrication and sealing of the MEMS devices.

In a pre-CMOS approach, the MEMS devices should be made of heat resistance materials such as silicon, polysilicon and silicon dioxide, so that they can stand the high temperature processing steps necessary for CMOS fabrication. An example of this is a silicon MEMS resonator fabricated in a substrate and covered by a deposited polysilicon layer that also acts as the electrodes. Silicon dioxide can be used as the sacrificial layer as well as post-release sealing material. The substrate surface can then be polished and get ready for fabrication of CMOS circuitry while the MEMS devices are safely embedded inside the substrate underneath the transistors. Interfaces between the MEMS and CMOS devices can be easily provided by vias formed during the CMOS process that extend to the substrate on top of the MEMS device.

In a post-CMOS approach, the processing of the MEMS device as well as the sealing process utilize low-temperature processed materials. As an example, the MEMS device can be fabricated using low temperature PECVD or metal layer depositions and plasma etching steps. The sacrificial material can be a polymer such as photoresist which can be easily removed in Oxygen plasma. The sealing material may contain PECVD layers and/or metals.

Thus, wafer-level encapsulation and sealing of electrostatic transducers, and the like, has been disclosed. It is to be understood that the above-described embodiments are merely illustrative of some of the many specific embodiments that represent applications of the principles discussed above. Clearly, numerous and other arrangements can be readily devised by those skilled in the art without departing from the scope of the invention.

What is claimed is:

1. Microelectromechanical apparatus, comprising:
a substrate;
one or more movable microelectromechanical elements formed in the substrate; and
one or more stationary elements that comprise electrically operative elements of the apparatus and that comprise a protective layer for the movable microelectromechanical elements.

2. The apparatus recited in claim 1 which comprises an electrostatic micromechanical resonator.

3. The apparatus recited in claim 2 wherein the stationary elements are sense and drive electrodes of the resonator.

4. The apparatus recited in claim 1 wherein the stationary elements cover the movable microelectromechanical elements on sides and top thereof and are separated therefrom by narrow gaps realized using a sacrificial layer.

5. The apparatus recited in claim 4 wherein the stationary elements have openings in them for sacrificial layer removal.

6. The apparatus recited in claim 5 wherein the openings in the stationary elements are closed by a nonconformal thin film.

7. The apparatus recited in claim 5 wherein the stationary elements completely cover the top surface of the movable elements.

8. The apparatus recited in claim 1 wherein the nonconformal thin film is a PECVD insulator film such as silicon dioxide or silicon nitride.

9. The apparatus recited in claim 1 further comprising a substantially impermeable thin film disposed on top of the sealed stationary elements to maintain a high level of vacuum and/or hermeticity for the encapsulated movable elements.

10. The apparatus recited in claim 9 wherein the substantially impermeable film is an evaporated metal film.

11. The apparatus recited in claim 1 wherein the impermeable film is a CMOS-compatible insulating thin film.

12. The apparatus recited in claim 11 wherein the CMOS-compatible insulating thin film comprises LPCVD silicon dioxide, silicon nitride, or polysilicon.

13. The apparatus recited in claim 1 further comprising one or more integrated circuit devices formed on the substrate beside or on top of the apparatus.

14. Acoustic resonator apparatus, comprising:
a silicon resonating micromechanical element formed in a substrate; and
one or more stationary electrodes separated from the resonating element by narrow capacitive gaps, wherein the electrodes extend on top of the resonating element to encapsulate it.

15. The apparatus recited in claim 14 wherein the electrodes are made of polycrystalline silicon.

16. The apparatus recited in claim 14 wherein the electrodes are sealed by a nonconformal thin film.

17. The apparatus recited in claim 16 wherein the nonconformal sealing film comprises an insulating PECVD thin film.

18. The apparatus recited in claim 14 further comprising a substantially impermeable film covering the nonconformal sealing film.

19. Microelectromechanical apparatus, comprising:
a substrate; and
a microelectromechanical structure formed in the substrate comprising one or more top electrodes, which electrodes encapsulate the apparatus.

20. The apparatus recited in claim 19 further comprising one or more integrated circuit devices formed on the substrate beside or on top of the microelectromechanical structure.
